(19) United States
(12) Patent Application Publication
(10) Pub. No.: US 2006/0257565 A1
(43) Pub. Date: Nov. 16, 2006

(54) Method of preparing catalyst layer for synthesis of carbon nanotubes and method of synthesizing carbon nanotubes using the same

(76) Inventors: Yong-Wan Jin, Seoul (KR); In-Taek Han, Seoul (KR); Deuk-Seok Chung, Seongnam-si (KR)

Correspondence Address: Robert E. Bushnell, Suite 300, 1522 K Street, N.W., Washington, DC, 20005, US

(21) Appl. No.: 11/356,240

(22) Filed: Feb. 17, 2006

(30) Foreign Application Priority Data
Feb. 19, 2005 (KR) 10-2005-0013903

(51) Int. Cl. B05D 3/12; C23C 16/00; B05D 3/10; B05D 3/00

(52) U.S. Cl. 427/248.1; 427/240; 427/532; 427/301

(57) ABSTRACT

A method of making a catalyst layer for synthesis of carbon nanotubes is provided. The method includes: coating a thin film formed of copolymer on a substrate; heat treating the thin film coated on the substrate to form a regular structure; removing a part of block copolymers that form the copolymer; depositing a catalyst base on the thin film from which a part of the block copolymers are removed; and removing the thin film to form a catalyst layer formed of a plurality of metal catalyst dots.

### CLAIM OF PRIORITY

This application makes reference to, incorporates the same herein, and claims all benefits accruing under 35 U.S.C. § 119 from an application earlier filed in the Korean Intellectual Property Office on the 19th Feb. 2005 and there duly assigned Serial No. 10-2005-0013903.

### BACKGROUND OF THE INVENTION

1. Field of the Invention

The present invention relates to a method of preparing a catalyst layer for synthesis of carbon nanotubes (CNTs) and a method of synthesizing CNTs using the same.

2. Description of the Related Art

In general, carbon nanotubes (CNTs) are cylindrical materials having a very fine diameter of several nanometers and a very large aspect ratio of about 10 to 1,000. In CNTs, carbon atoms are disposed in a hexagonal honeycomb structure and each carbon atom is combined with three adjacent carbon atoms. CNTs may have characteristics of a conductor or semiconductor depending on structures. It is known that electrical conductivity of CNTs having characteristics of a conductor is very high.

In addition, CNTs have characteristics such as very large mechanical strength, Young's modulus in a magnitude of tera-pascal, and high thermal conductivity etc. CNTs having excellent characteristics are used in variety of technical fields of devices such as field emission devices (FEDs), back-lights for a liquid crystal display (LCD), nano-electronic devices, actuators, batteries, transistors, catalyst supports' for a fuel cell, and super capacitors.

Methods of forming CNTs include vapor synthesis, electrical discharge, laser deposition, plasma chemical vapor deposition (CVD), and thermal CVD etc.

Vapor synthesis is a method of directly supplying a reaction gas and a catalyst metal to a reaction furnace without using a substrate, and synthesizing the reaction gas and the catalyst metal in a vapor state. The method is suitable for synthesis of CNTs in a bulk form.

In electrical discharge and laser deposition, the synthesis yield of CNTs is comparatively low, and it is not easy to control the diameter and length of CNTs. In addition, if electrical discharge or laser deposition is used, a large number of amorphous carbon particles as well as CNTs are generated, and thus, a complicated refinement process should be performed.

CVD such as plasma CVD, thermal CVD, or low pressure CVD (LP CVD) is used to form CNTs on a substrate.

In the plasma CVD, CNTs can be grown to be perpendicular to a substrate, and synthesized at a lower temperature than in the thermal CVD. Vertical growth of CNTs depends on the direction of an electric field applied between an anode and a cathode of the plasma CVD system. Thus, the direction of growth of CNTs can be controlled by changing the direction of the electric field. In addition, because the direction of growth of CNTs is uniform, the diameter, length, and density of CNTs can be easily controlled, and electron emission induced by an electric field can be easily performed. It is, however, difficult to uniformly grow CNTs, and because the diameter of CNTs that have been grown at a low temperature is comparatively large, CNTs have poor field emission characteristics.

In thermal CVD, CNTs have very excellent growth uniformity, and have smaller diameter than CNTs grown in the plasma CVD. The CNTs grown in the thermal CVD have a low threshold voltage of electron emission. However, unlike in the plasma CVD, an electric field is not applied to a substrate in the thermal CVD when CNTs are grown. Therefore, the direction of growth of CNTs is not uniform, and as gas decomposition is produced by thermal energy, CNTs require a high growth temperature.

In the CVD methods, in order to make the density of CNTs uniform, a catalyst base or a catalyst layer, which becomes a base for growth of CNTs, is first formed on a substrate before CNTs are grown on the substrate. Here, the catalyst base is a catalyst itself that becomes a base for growth of CNTs, or a material containing the catalyst.

When CNTs are grown based on the catalyst base, the density of CNTs cannot be easily controlled, and thus, the uniformity of CNTs is degraded. In addition, in order to form the catalyst base, expensive vacuum equipments should be used.

In order to make a patterned catalyst layer on a substrate, a predetermined catalyst metal is deposited on the substrate in the form of a thin film, and the metal film is patterned. In this method, however, high deposition cost for forming a thin film of the catalyst metal is required, and complicated patterning processes, such as exposure, development, etching, and strip processes, should be performed, and therefore, cost for the patterning processes increases.

Accordingly, a method of making a new catalyst layer, which effectively leads CNTs to be uniformly grown and the density of CNTs to be adjustable, is needed.

### SUMMARY OF THE INVENTION

The present invention provides a method of making a nano-size catalyst layer by controlling size, thickness, and density of the catalyst layer, a method of making a catalyst layer for synthesis of carbon nanotubes (CNTs) in which CNTs are grown, and a method of synthesizing CNTs using the same.

According to an aspect of the present invention, there is provided a method of preparing a catalyst layer for synthesis of carbon nanotubes, the method including: forming a thin film of a copolymer on a substrate, where the copolymer includes a plurality of block copolymers; heat treating the thin film coated on the substrate to form a regular structure; removing a least one block copolymer from the film; depositing a catalyst base on the thin film from which the block copolymer is removed; and removing the thin film to form a catalyst layer formed of a plurality of metal catalyst dots.

According to another aspect of the present invention, there is provided a method of growing carbon nanotubes, the method including: preparing a catalyst layer on a substrate and growing carbon nanotubes on the substrate on which the catalyst layer is formed. Preparing the catalyst layer includes: forming a thin film of a copolymer on a substrate; heat treating the thin film coated on the substrate to form a regular structure; removing at least one block copolymer that forms the copolymer; depositing a catalyst base on the thin film from which the block copolymer is removed; and removing the thin film to form a catalyst layer formed of a plurality of metal catalyst dots:

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1A through 1D illustrate a method of forming nano-size holes to make a catalyst layer for synthesis of carbon nanotubes (CNTs) formed according to the present invention;

FIGS. 2A through 2D illustrate a method of making a catalyst layer for synthesis of CNTs formed according to a first embodiment of the present invention;

FIGS. 3A through 3C illustrate a method of making a catalyst layer for synthesis of CNTs formed according to a second embodiment of the present invention;

FIG. 4 illustrate CNTs that have been grown on a catalyst layer made according to a first embodiment of the present invention;

FIG. 5 illustrate CNTs that have been grown on a catalyst layer made according to a second embodiment of the present invention;

FIG. 6 is a photo showing metal catalyst dots formed according to the present invention; and

FIG. 7 is a photo showing CNTs that have been grown on a catalyst layer made according to the present invention.

### DETAILED DESCRIPTION OF THE INVENTION

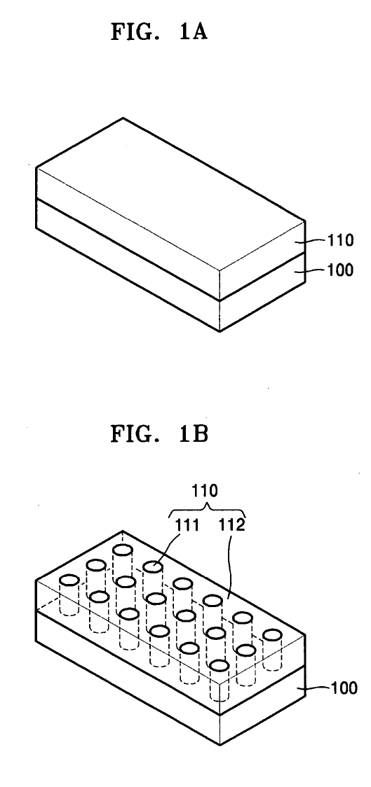

Referring to FIG. 1A, a thin film 110 is formed by coating a copolymer on a substrate 100.

A copolymer is an enormous molecule having large or complicated structure in which two chemically different types of monomers are jointed in the same polymer chain by a covalent bond. A structure of phase separation and a size of the copolymer vary according to chemical characteristics of a block, a length or molecular weight of a block, and volume composition. In general, a copolymer is made by combining multiple block copolymers having a pattern size of about several tens to hundreds of nanometers.

The structure of copolymer varies according to composition. For example, a diblock copolymer has a lamellar, gyroid, cylinder, or spherical structure, and a triblock or more complicated copolymer has more number of various structures.

Copolymers according to the present invention may have the following characteristics.

First, block copolymers that form a copolymer should have chemically different structures. Phase separation of block copolymer should be spontaneously induced, and the block copolymers should have a spherical structure so as to form metal catalyst dots. Second, etching selectivity should be different among different block copolymers, and therefore one of the block copolymers should be selectively and easily removed. Examples of copolymers include a polymer having an acrylrate group block such as polystyrene-polymethylmetaacrylrate (PS-PMMA), and a polymer having a block double bonded to a main chain, such as polystyrene-polybutadiene. In the present invention, PS-PMMA may be used for a copolymer. Third, a copolymer may induce self assembly. Fourth, even in a case that a copolymer has one block composed of inorganic polymer containing metal or ceramics and the other block composed of organic polymer, one block of copolymer may be easily removed using a difference in resistance to heat or plasma.

In the present invention, a thin film 110 is formed on a substrate 100 by spin-coating PS-PMMA on substrate 100 at a rpm (revolutions per minute) of 3000 for 60 seconds.

Referring to FIG. 1B, as thin film 110 is heated over a liquid crystal phase transition temperature (about 160° C.), a regular structure of PS-PMMA is formed. That is, if the thin film 110 is thermally treated, polymethylmetaacrylrate 111 is regularly arranged in a matrix of polystyrene 112 as shown in FIG. 1B.

During the heating process described above, polymethylmetaacrylrate 111 is heated to a liquid crystal phase transition temperature and slowly cooled down. Self assembly is induced during the heating process, and a regular structure is formed.

Referring to FIG. 1C, as an ultraviolet (UV) ray having a wavelength of 245 nanometers is irradiated onto thin film 110 on which polymethylmetaacrylrate 111 is regularly arranged in the matrix of polystyrene 112, cracks are produced only in the polymethylmetaacrylrate 111. Because polystyrene and polymethylmetaacrylrate have different responsiveness to ultraviolet light, cracks caused by UV rays are produced only in the polymethylmetaacrylrate 111.

Referring to FIG. 1D, only polymethylmetaacrylrate 111, in which cracks caused by UV rays occur, is removed from thin film 110 using a reactive ion etching (RIE) method. After the etching, nano-size porous holes 111a are formed in positions of the thin film 110 from which the polymethylmetaacrylrate 111 is removed. Only polystyrene 112 is left in the thin film 110.

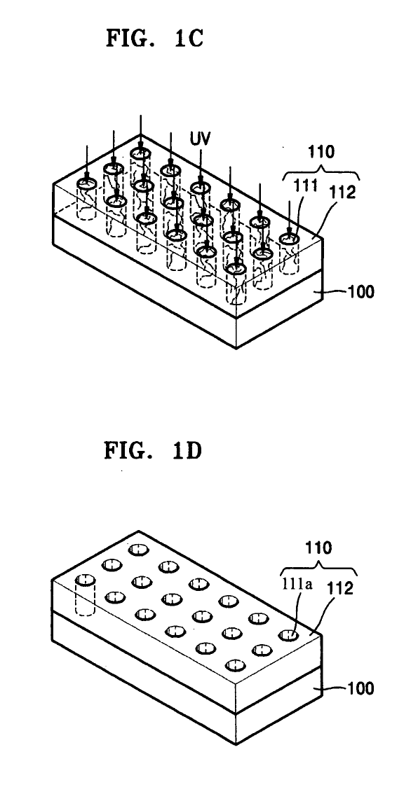

FIGS. 2A through 2D illustrate a method of making a catalyst layer for synthesis of CNTs formed according to a first embodiment of the present invention.

Referring to FIG. 2A, 1 to 10 nanometer thick aluminum (Al) is deposited on thin film 110 to form a buffer layer 130, where holes 111a are formed on thin film 110 after polymethylmetaacrylrate 111 is removed. 1 to 10 nanometer thick nickel (Ni) is deposited on the buffer layer 130 to form a catalyst metal precursor 140. Here, the catalyst metal precursor can be selected from any materials that can be changed to fine metal particles which become a base for growth of CNTs.

The aluminum which forms the buffer layer 130 and the nickel which is the catalyst metal precursor 140 sequentially penetrate the holes 111a, and fill the holes 111a.

Referring to FIG. 2B, substrate 100, on which a thin film 110 is formed with aluminum buffer layer 130 and nickel catalyst metal precursor 140, is dipped in an organic solvent such as N-methyl pyrrolidone to dissolve the polystyrene 112. Then, only a plurality of metal catalyst dots 150 remain on the substrate 100, and other residuals are removed. The metal catalyst dots 150 are formed of an aluminum dot 151 which was deposited to form a buffer layer and a nickel dot 152 which is a catalyst metal precursor.

The metal catalyst dots 150 may be formed by forming one nickel dot 152 on the top of an aluminum dot 151 as shown in FIG. 2B, or by forming a plurality of small size nickel dots 152 around the aluminum dot 151 as shown in FIG. 2C.

Referring to FIG. 2D, a silicon on glass (SOG) solution is coated on substrate 100 in which the metal catalyst dots 150 are formed, and is heat-treated to make a blocking layer 160, which is a silicon insulation layer (SiO₂ layer), and is formed between the metal catalyst dots 150.

The silicon on glass solution is spin-coated at rpm of 3000 using a spin coater. The silicon on glass solution is sequentially heat treated at 70° C. for 60 seconds for a first step, and then, 150° C. for 40 seconds for a second step, 250° C. for 40 seconds for a third step, and finally at 430° C. for 1 hour.

The purpose of forming a silicon blocking layer 160 (SiO2 insulation layer), which is produced by the processes of coating silicon on glass solution between the metal catalyst dots 150 and heat-treating the silicon on glass coating, is to prevent the metal catalyst dots 150 from being combined with one another producing chunks of metal catalysts at a temperature over 500° C.

In this case, as shown in FIG. 2D, nickel dot 152 protrudes from silicon (SiO₂) blocking layer 160. If the nickel dot 152 is buried in the silicon (SiO₂) blocking layer 160, the substrate 100 is dipped in a hydrogen fluoride (HF) solution for about 30 to 50 seconds, and a part of the surface of the silicon (SiO₂) blocking layer 160 is etched, making the nickel dot 150 protrude from the silicon (SiO₂) blocking layer 160.

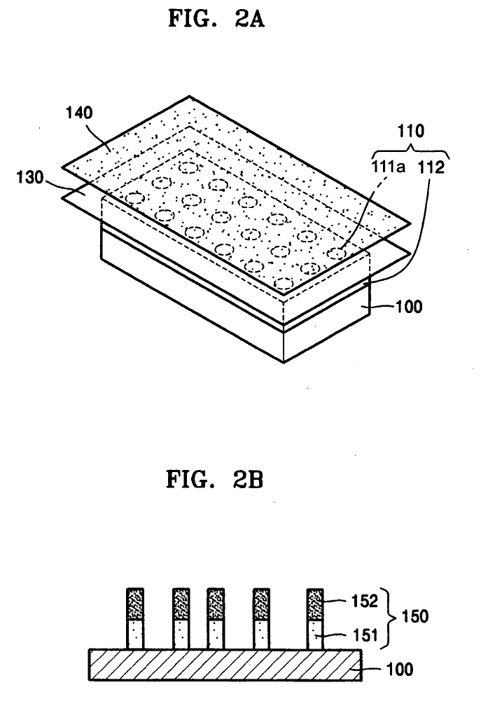

FIGS. 3A through 3C illustrate a method of making a catalyst layer for synthesis of CNTs formed according to a second embodiment of the present invention.

The method of forming nano-size holes to form a catalyst layer for synthesis of CNTs is the same as described for and shown in FIGS. 1A through 1D according to the principles of the present invention. Steps shown in FIGS. 3A through 3C are applied instead of steps shown in FIGS. 2A through 2D. The same reference numeral refers the same or comparable elements.

Referring to FIG. 3A, 1 to 10 nanometer thick nickel (Ni) is deposited on thin film 110 to form a catalyst metal precursor 140, where holes 111a are formed in positions of the thin film 110 from which polymethylmetaacrylrate 111 is removed. Here, the nickel (Ni), which is a catalyst metal precursor 140, penetrates the holes 111a, and fills the holes 111a.

Referring to FIG. 3B, substrate 100, on which a thin film 110 is formed with nickel catalyst metal precursor 140, is dipped in an organic solvent such as N-methyl pyrrolidone to dissolve the polystyrene 112. Only a plurality of metal catalyst dots 250 remain on the substrate 100, and other residuals are removed. In this embodiment, metal catalyst dots 250 are formed only of nickel which is the catalyst metal precursor.

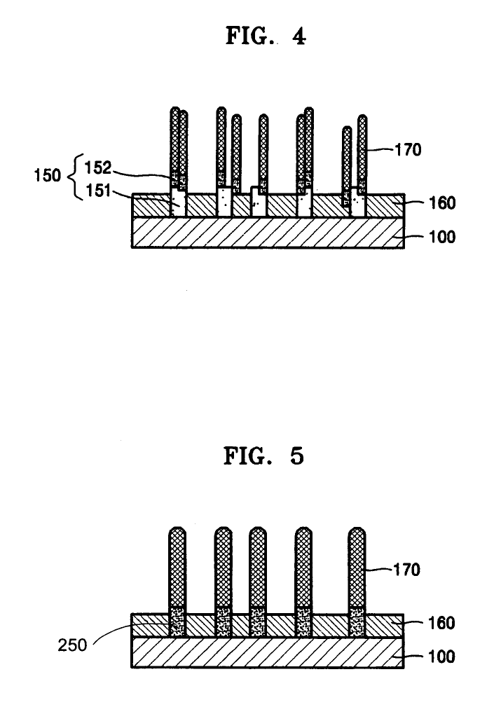

FIG. 6 shows a case where the metal catalyst dots 250 are formed on the substrate 100 after performing the process shown in FIG. 3B.

Referring to FIG. 3C, a silicon on glass (SOG) solution is coated on substrate 100 in which metal catalyst dots 250 remain, and is heat-treated to make a blocking layer 160 which is an silicon (SiO₂) insulation layer formed between the metal catalyst dots 250.

The a silicon on glass solution is spin-coated at rpm of 3000 using a spin coater. Heat treatment is performed in such a manner that heat is sequentially applied to the a silicon on glass solution at 70° C. for 60 seconds for a first step, 150° C. for 40 seconds for a second step, 250° C. for 40 seconds for third step, and finally at 430° C. for 1 hour.

The purpose of forming a silicon blocking layer 160 (SiO₂ insulation layer), which is produced by the processes of coating a silicon on glass solution between the metal catalyst dots 150 and heat-treating the a silicon on glass coating, is to prevent the metal catalyst dots 250 from being combined with one another producing chunks of metal catalyst at a temperature over 500° C.

In this case, as shown in FIG. 3C, metal catalyst dots 250 protrude from silicon (SiO₂) blocking layer 160. If the metal catalyst dots 250 is buried in the silicon (SiO₂) blocking layer 160, the substrate 100 is dipped in a hydrogen fluoride (HF) solution for about 30 to 50 seconds, and a part of the surface of the silicon (SiO₂) blocking layer 160 is etched making the metal catalyst dots 250 protrude from the silicon (SiO₂) blocking layer 160.

A catalyst layer for synthesis of CNTs is formed through the above described procedure.

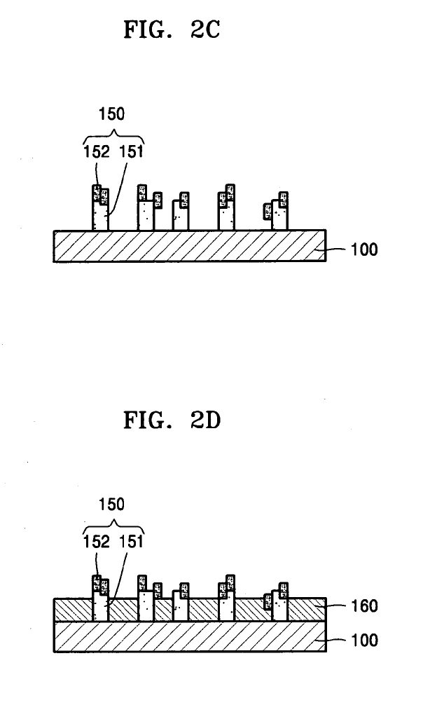

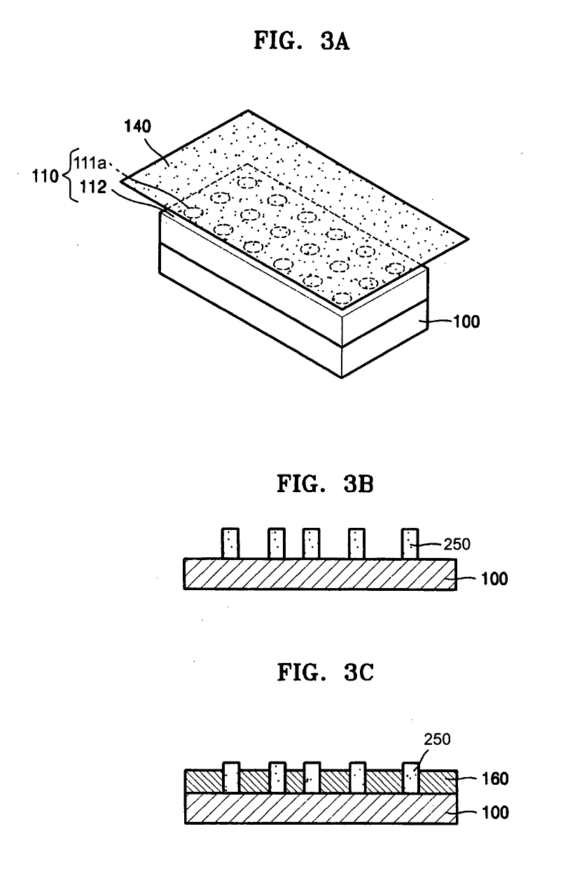

CNTs can be grown on the catalyst layer in various ways. Examples of growing catalyst layer are shown in FIGS. 4 and 5. FIG. 4 illustrates carbon nanotubes 170 that are grown on a catalyst layer made according to the first embodiment of the present invention, and FIG. 5 illustrates carbon nanotubes 170 that are grown on a catalyst layer made according to the second embodiment of the present invention. In these examples, a substrate 100, on which a catalyst layer is formed as a base for growth of CNTs, is placed in a reaction chamber, and then a carbon precursor gas is supplied into the reaction chamber. The carbon precursor gas is decomposed, supplying carbon to the catalyst layer, and therefore having carbon nanotubes 170 grown on the catalyst layer.

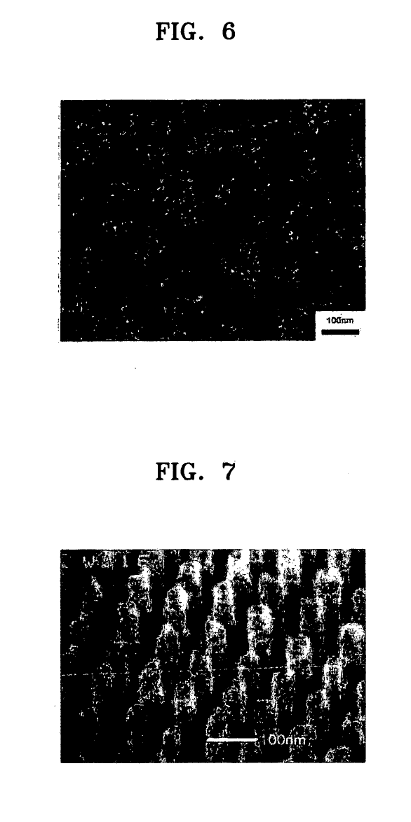

Specifically, the CNTs 170 can be grown by low pressure chemical vapor deposition (LP CVD), thermal CVD, plasma CVD, or a combined method thereof. In the present invention, the CNTs 170 may be grown by thermal CVD method. FIG. 7 is a photo showing the grown CNTs.

Acetylene, methane, propane, ethylene, carbon monoxide, carbon dioxide, alcohol or benzene may be used for a carbon precursor gas.

If the temperature of the reaction chamber is too low, the crystalline quality of CNTs may be degraded, and if the temperature of the reaction chamber is too high, CNTs may not be well formed. In consideration of these factors, the temperature of the reaction chamber may be optimized at about 450 to 1100° C.

As described above, the method of making a catalyst layer for synthesis of CNTs formed according to the principles of the present invention has the following advantages. First, this method enables to make fine patterns having a size less than several tens of nanometers, which is difficult to achieve by the use of an optical etching method. Complicated processing equipments are not required in this method. The process of making the catalyst layer is comparatively simple, and therefore reduces manufacturing cost. Second, the thickness of the catalyst layer can be controlled by controlling temperature for heat-treating a copolymer or by controlling depth of etching. The thickness of the catalyst layer also can be controlled by controlling a molecular weight of a copolymer. Therefore, the size of metal catalyst dots could be several nanometers to several tens of nanometers. Third, a diameter of a carbon nanotube can be uniformly controlled because of a blocking layer formed between the metal catalyst dots to prevent the metal catalyst dots from being combined together.

While the present invention has been particularly shown and described with reference to exemplary embodiments thereof, it will be understood by those skilled in the art that various changes in form and details may be made therein without departing from the spirit and scope of the invention as defined by the following claims.

What is claimed is:

1. A method of making a catalyst layer for growing carbon nanotubes, comprising:
forming a film of a copolymer on a substrate, the copolymer comprising a plurality of block copolymers;
heat-treating the film formed on the substrate;
removing at least one block copolymer from the film;
depositing a catalyst base on the film after the removing the block copolymer; and
forming an array of catalyst dots by selectively removing the film.

2. The method of claim 1, further comprised of forming a blocking layer between the catalyst dots after the step of forming an array of catalyst dots.

3. The method of claim 2, with the step of forming the blocking layer comprised of:
coating a silicon on glass solution on the substrate on which the plurality of catalyst dots are formed; and
heat-treating the silicon on glass solution coated on the substrate.

4. The method of claim 3, with the step of heat-treating the silicon on glass solution comprised of sequential steps of heating at approximately 70° C. for approximately 60 second, approximately 150° C. for approximately 40 seconds, approximately 250° C. for approximately 40 seconds, and at approximately 430° C. for approximately 1 hour.

5. The method of claim 1, wherein the plurality of block copolymers include polystyrene and polymethylmetaacrylrate.

6. The method of claim 5, with the step of removing at least one block copolymer from the film further comprised of removing polymethylmetaacrylrate.

7. The method of claim 1, with the forming the film of the copolymer on the substrate comprised of spin-coating the copolymer on the substrate.

8. The method of claim 1, with the heat-treating the film formed on the substrate comprised of heating the film over a liquid crystal phase transition temperature of the copolymer.

9. The method of claim 1, with the removing at least one block copolymer comprised of:
radiating ultraviolet light onto the film; and
performing reactive ion etching on the film after the radiating ultraviolet light.

10. The method of claim 1, wherein the catalyst base comprises nickel.

11. The method of claim 1, further comprised of depositing a buffer material after the step of removing at least one block copolymer and before the step of depositing the catalyst base.

12. The method of claim 11, wherein the buffer material comprises aluminum.

13. The method of claim 1, with the step of removing the film comprised of dipping the film in an organic solvent.

14. The method of claim 13, wherein the organic solvent comprises N-methyl pyrrolidone.

15. A method of growing carbon nanotubes, comprising:
preparing a catalyst layer comprising:
forming a film of a copolymer on a substrate, the copolymer comprising a plurality of block copolymers;
heat-treating the film formed on the substrate;
removing at least one block copolymer from the film;
depositing a catalyst base on the film after the removing the block copolymer; and
forming an array of catalyst dots by selectively removing the film; and
growing carbon nanotubes on the substrate on which the catalyst layer is formed.

16. The method of claim 15, comprised of growing carbon nanotubes during a thermal chemical vapor deposition process.

17. The method of claim 15, further comprised of forming a blocking layer between the catalyst dots after the step of forming an array of catalyst dots.

18. The method of claim 17, with the step of forming the blocking layer comprised of:
coating a silicon on glass solution on the substrate on which the plurality of catalyst dots are formed; and
heat-treating the silicon on glass solution coated on the substrate.

19. The method of claim 18, with the step of heat-treating the silicon on glass solution comprised of sequential steps of heating at approximately 70° C. for approximately 60 second, approximately 150° C. for approximately 40 seconds, approximately 250° C. for approximately 40 seconds, and at approximately 430° C. for approximately 1 hour.

20. The method of claim 15, wherein the plurality of block copolymers include polystyrene and polymethylmetaacrylrate.

21. The method of claim 20, with the step of removing at least one block copolymer from the film further comprised of removing polymethylmetaacrylrate.

22. The method of claim 15, with the forming the film of the copolymer on the substrate comprised of spin-coating the copolymer on the substrate.

23. The method of claim 15, with the heat-treating the film formed on the substrate comprised of heating the film over a liquid crystal phase transition temperature of the copolymer.

24. The method of claim 15, with the removing at least one block copolymer comprised of:
radiating ultraviolet light onto the film; and
performing reactive ion etching on the film after the radiating ultraviolet light.

25. The method of claim 15, wherein the catalyst base comprises nickel.

26. The method of claim 15, further comprised of depositing a buffer material after the step of removing at least one block copolymer and before the step of depositing the catalyst base.

27. The method of claim 15, with the step of removing the film comprised of dipping the film in an organic solvent.
